(19) United States
(12) Patent Application Publication
(10) Pub. No.: US 2009/0288863 A1
(43) Pub. Date: Nov. 26, 2009

(54) GLASS COMPOSITION WITH LOW COEFFICIENT OF THERMAL EXPANSION, GLASS FIBER, INSULATING LAYER OF PRINTED CIRCUIT BOARD AND PRINTED CIRCUIT BOARD

(75) Inventors: Jin-Cheol Kim, Hwaseong-si (KR); Jun-Rok Oh, Seoul (KR)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: SAMSUNG ELECTRO-MECHANICS CO., LTD., Suwon (KR)

(21) Appl. No.: 12/345,902

(22) Filed: Dec. 30, 2008

(30) Foreign Application Priority Data
May 21, 2008 (KR) 10-2008-0047145

(51) Int. Cl. H05K 1/02; C03C 3/083; C03C 3/085; C08K 3/40

(52) U.S. Cl. 174/258; 501/68; 501/69; 524/1

(57) ABSTRACT

The present invention relates to a glass composition having a low thermal expansion coefficient, a glass fiber, an insulating layer of printed circuit board and a printed circuit board. A glass fiber, an insulating layer of printed circuit board and a printed circuit board may be obtained by employing a glass composition including 40 to 60 parts by weight of silicon oxide, 20 to 40 parts by weight of aluminum oxide and 5 to 20 parts by weight of lithium oxide.

### CROSS-REFERENCE TO RELATED APPLICATIONS

This application claims the benefit of Korean Patent Application No. 10-2008-0047145 filed with the Korean Intellectual Property Office on May 21, 2008, the disclosure of which is incorporated herein by reference in its entirety.

### BACKGROUND

1. Technical Field

The present invention relates to a glass composition having a low thermal expansion coefficient, a glass fiber, an insulating layer of a printed circuit board and a printed circuit board.

2. Description of the Related Art

The demands in printed circuit boards are growing in response to the trends of electronic devices with smaller sizes. Such printed circuit boards are used to connect between active integrated circuits or between an integrated circuit and a passive component. Further, it fixes integrated circuits to function properly under service conditions and harsh conditions.

Thus, printed circuit boards having such functions are necessary to have electrical, mechanical and thermal stabilities. Strength, bending and dimensional stability against heat are critically important elements for the mechanical stability. Having a low thermal expansion coefficient is not any more optional but essential with development in the mounting technology demanding for lower electric permittivity of dyes, thinner substrate and 3-dimensional packaging technology and in the highly densified printed circuit board technology.

A printed circuit boards has a circuit pattern composed of an insulating layer and copper (Cu) in which thermal expansion coefficient of the copper is 17 ppm/□. An insulating layer of the printed circuit board has much higher thermal expansion coefficient than copper since the insulating layer includes high amount of a polymer resin. A glass fiber or a filler is used to catch up the difference in the thermal expansion coefficient of the insulating layer and the copper so that an insulating layer of a printed circuit board having a low thermal expansion coefficient may be used as integrated circuit (IC), printed circuit board or board, etc.

In manufacturing printed circuit boards, when an insulating layer of a printed circuit board having a thermal expansion coefficient which is similar to that of copper to be used, it reduces residual stress after the printed circuit boards are manufactured and removes deterioration such as delamination. A thermal expansion coefficient of an insulating layer of a printed circuit board can be controlled by the type of glass fiber used or an amount of filler used. A type of glass fiber can be changed from E-glass fiber to S-glass fiber or T-glass fiber. Such a change in the type of glass fiber may lower a thermal expansion coefficient. However, when a glass fiber is changed to S-glass fiber, even though a thermal expansion coefficient is lowered, it may cause different problems such as the formation of short which is caused that a glass fiber is damaged during the drilling process and thus a coating material penetrates into those holes when a pitch between via or through holes is reduced.

An increase of the amount of filler may be economical but it may cause the drill wear during the drilling process or leave residuals during the laser process. This problem may further invite increases in manufacturing cost and defect rate. Further, it may deteriorate the strength of peel between the insulating layer of a printed circuit board and the circuit pattern.

### SUMMARY

The present invention is to provide a glass composition having a low thermal expansion coefficient.

The present invention is to further provide a glass fiber, an insulating layer of a printed circuit board, and a printed circuit board manufactured by employing the glass composition having a low thermal expansion coefficient.

According to an embodiment of the invention, a glass composition including 40 to 60 parts by weight of silicon oxide, 20 to 40 parts by weight of aluminum oxide, and 5 to 20 parts by weight of lithium oxide is provided.

According to an embodiment of the invention, the glass composition may further include 0.2 to 6 parts by weight of at least one oxide chosen from barium oxide, magnesium oxide and zinc oxide.

According to an embodiment of the invention, the glass composition may further include 0.5 to 5 parts by weight of at least one oxide chosen from boron oxide and bismuth oxide.

According to an embodiment of the invention, the glass composition may further include 0.3 to 1 parts by weight of potassium oxide.

According to another embodiment of the invention, a glass fiber manufactured by employing the glass composition is provided.

According to another embodiment of the invention, is provided an insulating layer of a printed circuit board including the glass fiber manufactured by employing the glass composition, and a polymer resin in which the glass fiber is immersed.

According to another embodiment of the invention, is provided a printed circuit board including the insulating layer which includes the glass fiber manufactured by employing the glass composition, and a polymer resin in which the glass fiber is immersed; and a circuit pattern formed on the insulating layer of a printed circuit board.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a cross-sectional view of an insulating layer of a printed circuit board according to an embodiment of the invention.

FIG. 2 is a cross-sectional view of a glass fiber in an insulating layer of a printed circuit board according to an embodiment of the invention.

FIG. 3 is a cross-sectional view of a printed circuit board according to an embodiment of the invention.

### DETAILED DESCRIPTION

While the present invention has been described with reference to particular embodiments, it is to be appreciated that various changes and modifications may be made by those skilled in the art without departing from the spirit and scope of the present invention, as defined by the appended claims and their equivalents. Throughout the description of the present invention, when describing a certain technology is determined to evade the point of the present invention, the pertinent detailed description will be omitted.

The terms used in the description are intended to describe certain embodiments only, and shall by no means restrict the present invention. Unless clearly used otherwise, expressions in the singular number include a plural meaning. In the present description, an expression such as “comprising” or “consisting of” is intended to designate a characteristic, a number, a step, an operation, an element, a part or combinations thereof, and shall not be construed to preclude any presence or possibility of one or more other characteristics, numbers, steps, operations, elements, parts or combinations thereof.

Hereinafter, embodiments of a glass composition having a low thermal expansion coefficient, a glass fiber, an insulating layer of a printed circuit board, and a printed circuit board will be described in detail with reference to the accompanying drawings. Identical or corresponding elements will be given the same reference numerals, regardless of the figure number, and any redundant description of the identical or corresponding elements will not be repeated.

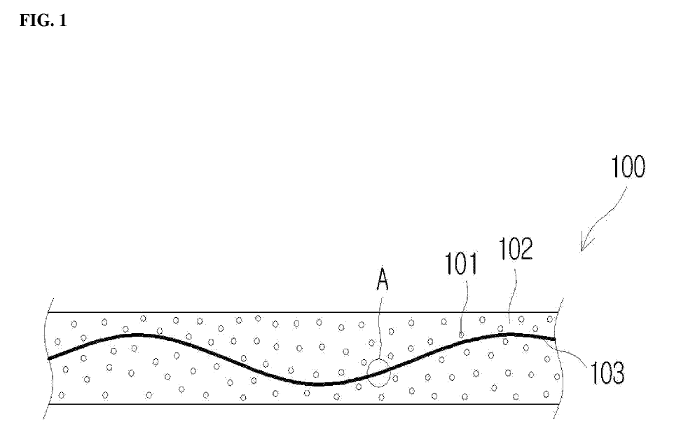

FIG. 1 is a cross-sectional view of an insulating layer of a printed circuit board. The insulating layer 100 of a printed circuit board includes a polymer resin 102, a filler 101, and a glass fiber 103. The polymer resin 102 may be an epoxy resin and a thermal expansion coefficient of the epoxy resin may be 70 to 100 ppm/° C.

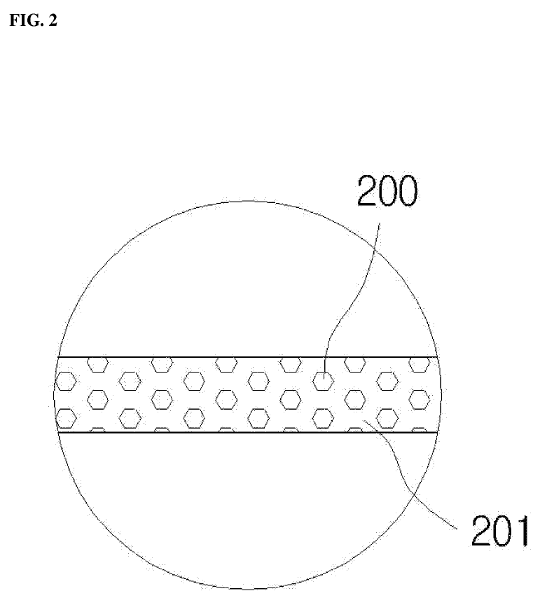

FIG. 2 is a cross-sectional view of the glass fiber 103 which is a magnified view of A part in FIG. 1. The glass fiber 103 may include eucryptite 200 and the residue 201 of the glass composition after the eucryptite 200 is formed with the glass composition.

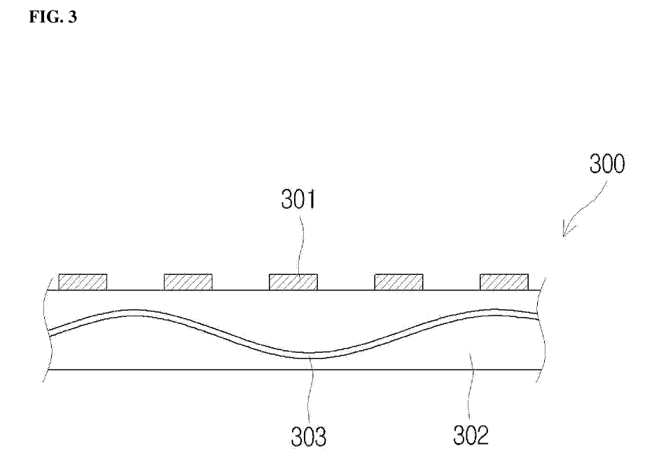

FIG. 3 is a cross-sectional view of a printed circuit board 300. The printed circuit board 300 includes a circuit pattern 301, a polymer resin 302 and a glass fiber 303.

The glass fiber 103 of FIG. 1 and the glass fiber 303 of FIG. 3 are identical.

The polymer resin 102 of FIG. 1 may have an identical element to the polymer resin 302 of FIG. 2 and may or may not include the filler 101.

An embodiment of the present invention provides a method to lower a thermal expansion coefficient by using eucryptite 200 which is able to lower a thermal expansion coefficient when temperature increases. An embodiment of the invention further provides a method to lower a thermal expansion coefficient of the insulating layer 100 of a printed circuit board without increasing an amount of the filler 101 which causes manufacturing cost increase and deterioration of drill wear and peel strength.

Oxide compounds of embodiments of the invention are prepared by a typical preparation of powders and melt through a heat treatment at 700 to 1100° C.

The thermal expansion coefficient of the glass fiber 103 may be −5 to 0 ppm/° C. in accordance with parts by weight of component materials of the glass composition. A temperature range where the thermal expansion coefficient is measured is 30 to 300° C.

According to an embodiment of the present invention, the glass composition including eucryptite (LiAlSiO₄,) 200 which is crystallized of silicon oxide, aluminum oxide and lithium oxide is used as the glass fiber 103, instead of the conventional glass fiber in order to lower the thermal expansion coefficient of the insulating layer 100 of a printed circuit board.

An amount of constituent materials of the glass composition and an amount of the eucryptite 200 may be adjusted to use the glass composition as the glass fiber 103. Silicon oxide (SiO₂), lithium oxide (Li₂O) and aluminum oxide (Al₂O₃) may be used in a mole ratio to form the eucryptite (LiAlSiO₄) 200 and the residue of the oxides may be remained in the glass fiber 103 as the residual glass composition 201.

A glass fiber is typically formed by melting a glass composition at 1000□ or higher and then passing through the melted composition through a nozzle. Since the eucryptite 200 is a crystallized glass and a high temperature of 2000° C. or above is required to melt a crystallized glass, it is difficult to form glass fibers thereof.

According to an embodiment of the invention, a glass composition including the crystallized eucryptite 200 which can be melted at a temperature of 1200° C. or lower is provided and the glass composition is formed into the glass fiber 103. When the temperature is above 1200° C., it is not economical due to high cost for excessively increasing temperature and insulating a furnace.

A glass composition according to an embodiment of the invention may include 40 to 60 parts by weight of silicon oxide, 20 to 40 parts by weight of aluminum oxide and 5 to 20 parts by weight of lithium oxide. As described above, 20 to 80 parts by weight of eucryptite 200 may be formed in accordance with the mole ratio of the oxides. When less than 20 parts by weight of eucryptite 200 is formed, it is not sufficient to lower the thermal expansion coefficient. On the other hand when more than 80 parts by weight of eucryptite 200 is formed, a melting temperature of the glass composition may become too high to form the glass composition into the glass fiber 103.

The glass composition may include 40 to 60 parts by weight of silicon oxide, preferably 45 to 55 parts by weight. When the amount of silicon oxide is used more than the maximum range, the thermal expansion coefficient may become lowered but the melting temperature of the glass composition may become too high. On the other hand, when the amount is used less than the minimum range, a content of eucryptite 200 within the glass composition may become reduced and thus it may be difficult to obtain a desired thermal expansion coefficient of the glass composition.

The glass composition may include 20 to 40 parts by weight of aluminum oxide, preferably 25 to 38 parts by weight. When the amount of aluminum oxide is used more than the maximum range, the thermal expansion coefficient may become lowered but the melting temperature of the glass composition may become too high. On the other hand, when the amount is used less than the minimum range, it may deteriorate a water resistance.

The glass composition may include 5 to 20 parts by weight of lithium oxide, preferably 6 to 18 parts by weight. When the amount of lithium oxide is used more than the maximum range, the thermal expansion coefficient may become lowered but a degree of crystallinity of the glass composition may become increase and the melting temperature of the glass composition may also become too high. On the other hand, when the amount is used less than the minimum range, a content of eucryptite 200 within the glass composition may become reduced and thus it may be difficult to obtain a desired thermal expansion coefficient of the glass composition.

According to an embodiment of the invention, the glass composition may further include at least one oxide chosen from barium oxide, magnesium oxide and zinc oxide. The barium oxide not only stabilizes the glass composition against radiation but also helps melting the glass composition. The magnesium oxide also helps melting the glass composition. The zinc oxide reduces a viscosity of the glass composition and enforces a resistance of the glass composition.

Barium oxide, magnesium oxide or zinc oxide may be used alone or a mixture of two or more in a range of 0.2 to 6 parts by weight. When barium oxide is used more than the desired amount, it may increase the weight of the glass composition significantly, when magnesium oxide is used more than the desired amount, it may deteriorate the durability of the glass composition with excess use of an alkaline earth metal oxide, and when zinc oxide is used more than the desired amount, cost for manufacturing the glass composition may significantly increase.

According to an embodiment of the invention, the glass composition may further include 0.5 to 5 parts by weight of at least one oxide chosen from boron oxide and bismuth oxide.

Boron oxide may improve radiation safety of the glass composition and provide a glass having a high emissivity and also act as a fluxing agent. However, when boron oxide is used in an excess amount, it may deteriorate the durability of the glass composition. Bismuth oxide may lower the melting temperature of the glass composition but when it is used in an excess amount, it may increase the thermal expansion coefficient of the glass composition. Thus, boron oxide or bismuth oxide is used within a range of 0.5 to 5 parts by weight, preferably 1 to 3 parts by weight.

According to an embodiment of the invention, the glass composition may further include 0.3 to 1 parts by weight of potassium oxide. The alkaline metal oxide such as potassium oxide is a useful fluxing agent for the glass composition but when it is used in an excess amount, it may deteriorate the durability of the glass composition. Thus it is used in a range of 0.3 to 1 parts by weight, preferably 0.3 to 0.5 parts by weight.

According to another aspect of the invention, a glass fiber 103 prepared by using the glass composition is provided. As described above, the glass composition of the invention has a low melting temperature so that it is easy to form the glass composition into the glass fiber 103.

According to another aspect of the invention, an insulating layer 100 of a printed circuit board including the glass fiber 103 and a polymer resin 302, in which the glass fiber 103 is immersed, is provided.

According to another aspect of the invention, a printed circuit board 300, including the insulating layer 100 of a printed circuit board and a circuit pattern formed on the insulating layer 100 of a printed circuit board, is provided.

Since the glass fiber 103 has a lower thermal expansion coefficient that the conventional E-glass fiber, it may not only provide manufacturing convenience but also lower thermal expansion coefficient of the insulating layer 100 of a printed circuit board and the printed circuit board 300.

### EXAMPLES 1 to 5

A glass fiber was prepared by using a composition including 46.0 parts by weight of silicon oxide, 38.0 parts by weight of aluminum oxide, 11.0 parts by weight of lithium oxide, 3.0 parts by weight of boron oxide, 0.3 parts by weight of barium oxide, 0.2 parts by weight of magnesium oxide, 0.2 parts by weight of zinc oxide, 1.0 parts by weight of bismuth oxide and 0.3 parts by weight of potassium oxide in Example 1. The glass fiber had a melting temperature of 960° C. and a thermal expansion coefficient of −2 ppm/° C. and included 40 parts by weight of eucryptite 200.

A glass fiber was prepared by using a composition including 56.0 parts by weight of silicon oxide, 25.5 parts by weight of aluminum oxide, 6.2 parts by weight of lithium oxide, 5.2 parts by weight of barium oxide, 0.6 parts by weight of magnesium oxide, 2.7 parts by weight of zinc oxide, 3.3 parts by weight of bismuth oxide and 0.5 parts by weight of potassium oxide in Example 2. The prepared glass fiber had a melting temperature of 980° C. and a thermal expansion coefficient of −3 ppm/° C. and included 53 parts by weight of eucryptite 200.

A glass fiber was prepared by using a composition including 47.8 parts by weight of silicon oxide, 32.1 parts by weight of aluminum oxide, 18.1 parts by weight of lithium oxide, 1.5 parts by weight of barium oxide and 0.5 parts by weight of magnesium oxide in Example 3. The prepared glass fiber had a melting temperature of 930° C. and a thermal expansion coefficient of −4 ppm/° C. and included 65 parts by weight of eucryptite 200.

A glass fiber was prepared by using a composition including 48.0 parts by weight of silicon oxide, 38.0 parts by weight of aluminum oxide, 11.0 parts by weight of lithium oxide, 0.5 parts by weight of boron oxide, 0.5 parts by weight of barium oxide, 0.5 parts by weight of magnesium oxide, 1.0 parts by weight of zinc oxide and 0.5 parts by weight of bismuth oxide in Example 4. The prepared glass fiber had a melting temperature of 1020° C. and a thermal expansion coefficient of 0 ppm/° C. and included 25 parts by weight of eucryptite 200.

A glass fiber was prepared by using a composition including 45.5 parts by weight of silicon oxide, 39.0 parts by weight of aluminum oxide, 11.0 parts by weight of lithium oxide, 1.5 parts by weight of barium oxide, 1.5 parts by weight of zinc oxide and 1.5 parts by weight of bismuth oxide in Example 5. The prepared glass fiber had a melting temperature of 1070° C. and a thermal expansion coefficient of −5 ppm/° C. and included 80 parts by weight of eucryptite 200.

A mole ration and characteristics of the glass composition of Examples are summarized in Table 1.

TABLE 1
Mole ratio and characteristics of the glass composition

| | | Example 1 | Example 2 | Example 3 | Example 4 | Example 5 |
|---|---|---|---|---|---|---|
| melting temperature (° C.) | | 960 | 980 | 930 | 1020 | 1070 |
| parts by weight of eucryptite | | 40 | 53 | 65 | 25 | 80 |
| thermal expansion | | −2 | −3 | −4 | 0 | −5 |
| coefficient (ppm/° C.) | | | | | | |
| Glass | SiO₂ | 46.0 | 56.0 | 47.8 | 48.0 | 45.5 |
| composition | Al₂O₃ | 38.0 | 25.5 | 32.1 | 38.0 | 39.0 |
| (parts by | Li₂O | 11.0 | 6.2 | 18.1 | 11.0 | 11.0 |
| weight %) | B₂O₃ | 3.0 | — | — | 0.5 | — |
| | BaO | 0.3 | 5.2 | 1.5 | 0.5 | 1.5 |
| | MgO | 0.2 | 0.6 | 0.5 | 0.5 | — |
| | ZnO | 0.2 | 2.7 | — | 1.0 | 1.5 |
| | Bi₂O₃ | 1.0 | 3.3 | — | 0.5 | 1.5 |
| | K₂O | 0.3 | 0.5 | — | — | — |

### COMPARATIVE EXAMPLES 1 to 4

A E-glass fiber was prepared by using a composition including a mixture of 52 to 56 parts by weight of silicon oxide, 12 to 16 parts by weight of aluminum oxide, 5 to 10 parts by weight of boron oxide, 16 to 25 parts by weight of calcium oxide, 0 to 6 parts by weight of magnesium oxide, 0 to 2 parts by weight of sodium oxide and potassium oxide and 0 to 1.5 parts by weight of titanium oxide in Comparative Example 1. The prepared E-glass fiber had a thermal expansion coefficient of 5.5 ppm/° C.

A T-glass fiber was prepared by using a composition including 64.3 parts by weight of silicon oxide, 24.8 parts by weight of aluminum oxide, more than 0.01 parts by weight of boron oxide, more than 0.01 parts by weight of calcium oxide, 10.3 parts by weight of magnesium oxide, and 0.27 parts by weight of a mixture of sodium oxide and potassium oxide in Comparative Example 2. The prepared T-glass fiber had a thermal expansion coefficient of 2.9 ppm/° C. The T-glass fiber had the lowest thermal expansion coefficient among glass fibers prepared in Comparative Examples. When the T-glass fiber was used, it allowed providing an insulating layer of a printed circuit board having a thermal expansion coefficient of 10 ppm/° C. or lower. However, the T-glass fiber was easily broken-down during a drilling process. Such damages of the T-glass fiber further caused a short between holes during a coating process.

A NCR-glass fiber was prepared by using a composition including 58.2 parts by weight of silicon oxide, 11.3 parts by weight of aluminum oxide, 22.0 parts by weight of calcium oxide, 2.7 parts by weight of magnesium oxide, 0.1 parts by weight of sodium oxide, 0.5 parts by weight of potassium oxide, 2.2 parts by weight of titanium oxide and 2.7 parts by weight of zinc oxide in Comparative Example 3. The prepared NCR-glass fiber had a thermal expansion coefficient of 6.0 ppm/° C.

A NE-glass fiber was prepared by using a composition including 52 to 56 parts by weight of silicon oxide, 10 to 15 parts by weight of aluminum oxide, 15 to 20 parts by weight of boron oxide, 0 to 10 parts by weight of calcium oxide, 0 to 5 parts by weight of magnesium oxide, 0 to 1 parts by weight of titanium oxide and 0.5 to 5 parts by weight of zinc oxide in Comparative Example 43. The prepared NE-glass fiber had a thermal expansion coefficient of 3.3 ppm/° C.

Mole ratios and characteristics of the glass compositions of Comparative Examples were summarized in Table 2.

TABLE 2
Mole ratio and characteristics of the glass composition

| | | E-Glass | T_Glass | NCR_Glass | NE-Glass |
|---|---|---|---|---|---|
| | | (Comp. Ex. 1) | (Comp. Ex. 2) | (Comp. Ex. 3) | (Comp. Ex. 4) |
| thermal expansion | | 5.5 | 2.9 | 6.0 | 3.3 |
| coefficient (ppm/° C.) | | | | | |
| Glass | SiO₂ | 52~56 | 64.3 | 58.2 | 52~56 |
| composition | Al₂O₃ | 12~16 | 24.8 | 11.3 | 10~15 |
| | B₂O₃ | 5~10 | <0.01 | — | 15~20 |
| | CaO | 16~25 | <0.01 | 22.0 | 0~10 |
| | MgO | 0~6 | 10.3 | 2.7 | 0~5 |
| | Na₂O | — | — | 0.1 | — |
| | K₂O | — | — | 0.5 | — |
| | Li₂O | — | — | — | — |
| | Na₂O + | 0~2 | 0.27 | — | — |
| | K₂O | | | | |
| | TiO₂ | 0~1.5 | — | 2.2 | 0~1 |
| | ZnO | — | — | 2.7 | 0.5~5 |
| | ZrO₂ | — | — | — | — |

While the present invention has been described with reference to particular embodiments, it is to be appreciated that various changes and modifications may be made by those skilled in the art without departing from the spirit and scope of the present invention, as defined by the appended claims and their equivalents.

1. A glass composition comprising:
40 to 60 parts by weight of silicon oxide;
20 to 40 parts by weight of aluminum oxide; and
5 to 20 parts by weight of lithium oxide.

2. The glass composition of claim 1, further comprising 0.3 to 1 parts by weight of potassium oxide.

3. The glass composition of claim 1, further compromising 0.5 to 5 parts by weight of at least one oxide selected from the group consisting of barium oxide, magnesium oxide and zinc oxide.

4. The glass composition of claim 3, further comprising 0.3 to 1 parts by weight of potassium oxide.

5. The glass composition of claim 1, further comprising 0.2 to 6 parts by weight of at least one oxide selected from the group consisting of barium oxide, magnesium oxide and zinc oxide.

6. The glass composition of claim 5, further comprising 0.3 to 1 parts by weight of potassium oxide.

7. The glass composition of claim 5, further comprising 0.5 to 5 parts by weight of at least one oxide selected from the group consisting of boron oxide and bismuth oxide.

8. The glass composition of claim 7, further comprising 0.3 to 1 parts by weight of potassium oxide.

9. A glass fiber manufactured by using the glass composition of claim 1.

10. A glass fiber manufactured by using the glass composition of claim 2.

11. An insulating layer of a printed circuit board comprising:
the glass fiber of claim 9; and
a polymer resin in which the glass fiber is immersed.

12. A printed circuit board comprising:
the insulating layer of claim 10; and
a circuit pattern formed on the insulating layer of a printed circuit board.
